(19) United States
(12) Patent Application Publication
(10) Pub. No.: US 2026/0298625 A1
(43) Pub. Date: Oct. 1, 2026

(54) METHOD AND SYSTEM FOR MEASURING AND CORRECTING DIE ALIGNMENT ERROR

(71) Applicant: CANON KABUSHIKI KAISHA, Tokyo (JP)

(72) Inventor: Nilabh K. ROY, Cedar Park, TX (US)

(21) Appl. No.: 19/094,165

(22) Filed: Mar. 28, 2025

(51) Int. Cl. H01L 23/00; G01B 11/27; H01L 21/66

(52) U.S. Cl. CPC G01B 11/272; H10P 74/203; H10W 72/07178

(57) ABSTRACT

A method of correcting an alignment error of a die with respect to a first substrate includes capturing a first image on an object, the first image includes a first metrology mark with a first pattern, capturing a second image on a surface of the die, the second image includes a second metrology mark, the second metrology mark includes a second pattern captured while the die is moving toward the first substrate, superposing the first pattern and the second pattern to form a simulated interference pattern, determining a metrology mark error based on the simulated interference pattern in X, Y and θZ directions, obtaining the die alignment error based on alignment marks placement error of a second substrate of the die, and the metrology mark error, and adjusting a position of the die, before the die is brought into contact with the first substrate, based on the die alignment error.

### BACKGROUND

### Field of Art

The present disclosure relates to semiconductor processing, and more specifically relates to systems and methods for measuring alignment errors in bonding semiconductor materials.

### Description of the Related Art

Currently, in a chip to wafer bonding process, the overlay metrology is not well established to measure overlay errors between the bonded dies and substrate with less than 10 nm resolution.

In order to properly measure an alignment error of a die, dedicated Infrared (IR) metrology marks and zones are often allocated on the dies for placing the alignment marks. However, such dedicated zones are devoid of any circuitry metal features because these circuitries can degrade the IR imaging quality and resolution. Thus, the usable areas on the dies will be reduced due to these dedicated zones. Also, as the metrology is performed by IR imaging device through the dies, metrology resolution may be degraded due to longer IR wavelengths and thus very hard to achieve less than 10 nm overlay measurement resolution.

It is desirable to minimize the space required for the alignment markings. Further, it is desirable to measure and correct alignment errors of a die in real time before bonding a die on a product substrate.

### SUMMARY

According to an aspect of the present disclosure, a bonding system includes a bonding chuck that releasably secures a die, a substrate chuck that releasably secures a first substrate, an imaging device that captures a first image on an object, the first image includes a first metrology mark, the first metrology mark includes a first pattern, wherein the object is one of the first substrate; and a frame that has a fixed positional relationship with the substrate chuck, and captures a second image on a surface of the die, the second image includes a second metrology mark, the second metrology mark includes a second pattern captured while the bonding chuck is moving toward the substrate chuck, at least one memory storing instructions and at least one processor that executes the stored instructions, which cause the at least one processor to receive the first image and the second image, superpose the first pattern and the second pattern to form a simulated interference pattern, determine a metrology mark error based on the simulated interference pattern in X, Y and θZ directions, obtain the die alignment error based on alignment marks placement error of a second substrate of the die, and the metrology mark error, and sending instructions to adjust a position of the die chuck relative to the substrate chuck, before the die is brought into contact with the first substrate, based on the die alignment error. Further aspects of the present invention are a method of using the bonding system and a method of manufacturing an article using the bonding system.

Further features of the present disclosure will become apparent from the following description of exemplary embodiments with reference to the attached drawings.

### BRIEF DESCRIPTION OF THE DRAWINGS

FIG. 1 is a cross-section view of the metrology and bonding apparatus according to an embodiment of the present disclosure.

FIG. 2A is a top-down view of a die that includes a pair of die metrology mark according to an embodiment of the present disclosure; FIG. 2B illustrates an example of using a substrate metrology mark and a die metrology mark to form an interference pattern.

FIGS. 3A and 3B illustrate exemplary operations of the metrology and bonding apparatus for capturing substrate metrology marks and die metrology marks.

FIGS. 4A and 4B illustrate examples of forming simulated interference patterns.

FIG. 5 is a flowchart illustrating an exemplary process for determining die alignment errors and bonding a die to a destination substrate.

FIG. 6 illustrates an embodiment for capturing a die metrology mark.

FIG. 7 illustrates an error caused by a z-motion movement of the optical device.

FIGS. 8A and 8B illustrate an active side and the opposite non-active side of the source substrate prior to a singulation process.

FIG. 9 illustrates an exemplary configuration for measuring alignment marks of the source substrate.

### DESCRIPTION OF THE EMBODIMENTS

Exemplary embodiments of the present disclosure will be described in detail below with reference to the attached drawings. It shall be understood that the drawings are shown for illustrative purposes, and they are not necessarily drawn to scale. The following exemplary embodiments are not intended to limit the claimed disclosure, and not all combinations of features described in the exemplary embodiments are necessarily deemed to be essential. The same components are denoted by the same reference numerals, and descriptions thereof are omitted.

In the specification and the accompanying drawings, directions will be typically indicated on an XYZ coordinate system in which a surface parallel to a horizontal surface is defined as the X-Y plane. Directions parallel to the X-axis, the Y-axis, and the Z-axis of the XYZ coordinate system are defined as the X direction, the Y direction, and the Z direction, respectively. A rotation about the X-axis, a rotation about the Y-axis, and a rotation about the Z-axis are defined as θX, θY, and θZ, respectively. Control and driving (movement) concerning the X-axis, the Y-axis, and the Z-axis mean control or driving (movement) concerning a direction parallel to the X-axis, a direction parallel to the Y-axis, and a direction parallel to the Z-axis, respectively. In addition, control or driving concerning the θX-axis, the θY-axis, and the θZ-axis means control or driving concerning a rotation about an axis parallel to the X-axis, a rotation about an axis parallel to the Y-axis, and a rotation about an axis parallel to the Z-axis, respectively.

In embodiments to be described later, an example in which a substrate (or wafer) on which semiconductor devices are formed and a die (or a chip) obtained by dividing into pieces a substrate on which semiconductor devices are formed will be explained. However, various changes and modifications can be made within the scope of the present disclosure. In the embodiments to be described later, various temporary or permanent bonding methods can be applied as a bonding method. Examples of the bonding method are bonding using an adhesive, temporary bonding using a temporal adhesive, bonding by hybrid bonding, atomic diffusion bonding, vacuum bonding, and bump bonding.

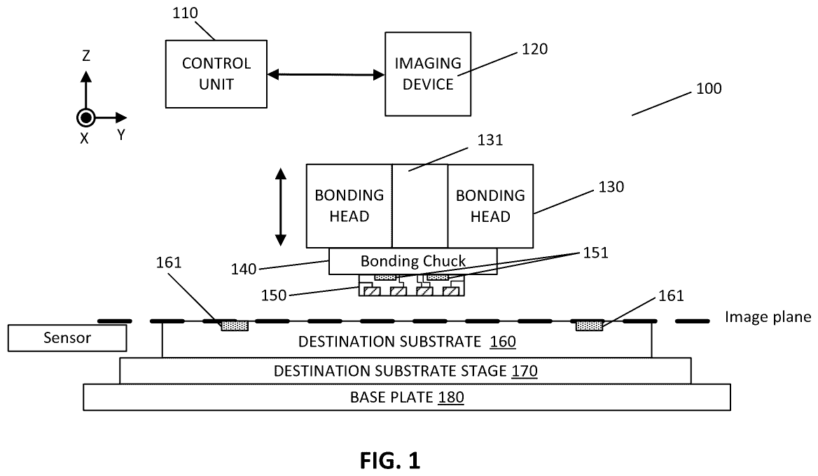

FIG. 1 illustrates an exemplary configuration of a metrology and bonding apparatus 100. The metrology and bonding apparatus 100 includes a control unit 110 (controller), an imaging unit 120, a bonding head 130 with cavity 131, a bonding chuck 140, a destination substrate 160, a substrate stage 170, and a base plate 180. For illustrative purposes, a die 150 is removably secured by bonding chuck 140. The die 150 includes one or more die metrology marks 151. Destination substrate 160 includes one or more substrate metrology mark 161. The substrate stage 170 includes a substrate chuck (not shown) which releasably secures the destination substrate 160 to the substrate stage 170. The substrate stage 170 is connected to a base plate 180. The substrate stage 170 uses its internal driving mechanism which includes various motors and actuators to position the destination substrate 160 at a desired position relative to the base plate 180. It shall be understood while one of each element is described in this example, more than one of each element may be included in the metrology and bonding apparatus 100. For instance, more than one imaging unit and more than one control unit may be included in the metrology and bonding apparatus 100. In an alternative embodiment, the substrate metrology mark 161 is not located on the substrate, rather, the substrate metrology mark 161 is located on a frame (not shown) connected to the substrate stage 170 or base plate 180. The frame can be a part of the substrate chuck or adjacent to the substrate chuck. When the substrate stage 170 moves the substrate chuck (which is holding the substrate), the frame with the substrate metrology marks 161 moves in concert with the substrate chuck. When the substrate metrology marks 161 are located on the frame they may be located at an image plane that is above an expected bonding plane of the bonding system.

The imaging unit 120 may be an image capture device or a microscope that includes an imaging sensor such as a complementary metal oxide semiconductor (CMOS) or a charge-coupled device (CCD) with numerical aperture (NA) of 0.02 to 0.3, displacement magnification (amplification due to moiré interference pattern of gratings) of 10-200×, optics resolution with 1-20× optical magnification of 1-100 nm. The imaging unit 120 can include a driving mechanism (not shown) which enables the imaging unit 120 to move in the X, Y, Z, and θZ directions. Such driving mechanism may consist of various motors and actuators. As a result, the imaging unit 120 is capable of capturing images at any location on the destination substrate 160 or a frame. The captured images can then be transferred to a memory of the control unit 110.

The control unit 110 includes at least one processor (e.g., Central Processing Unit (CPU)) and at least one memory storing instructions to be performed by the CPU, and controls the entirety (respective parts) of the metrology and bonding apparatus 100. Furthermore, the control unit 110 controls the metrology measurement, the alignment processing, and other processing associated therewith. Note that the number of the control unit is not limited to one, and more than one control unit may be used to control the respective parts.

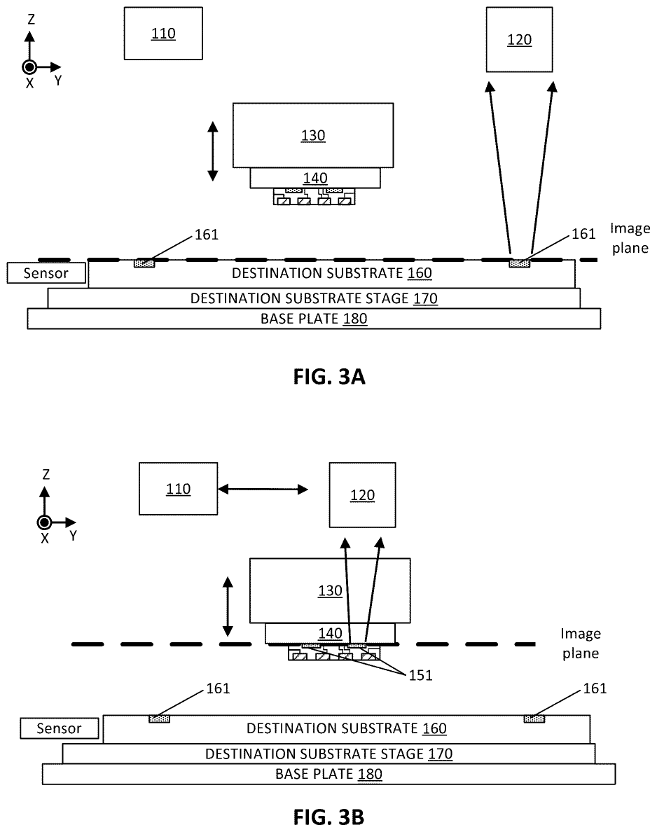

FIGS. 3A and 3B illustrate exemplary operations of the metrology and bonding apparatus for capturing substrate metrology marks and die metrology marks corresponding to the metrology and bonding apparatus 100 of FIG. 1 described above. As shown in FIG. 3A, prior to capturing the images, imaging unit 120 is moved to the nominal position above of a substrate metrology mark 161 by a driving mechanism with precision positioning capability using sensing such as interferometers. This nominal position information of the substrate metrology mark 151 may be available from design files (e.g., gds files) for the driving mechanism to drive to. The control unit 110 then causes the imaging unit 120 to capture the image of the substrate metrology marks 161 and store the image of the substrate metrology mark 161. The image may then be cropped, filtered, denoised for further processing. The substrate metrology mark 161 is recorded in a global or tool coordinate system. The positional and orientational information of the substrate metrology mark 161 in the X, Y, and θZ coordinate is subsequently stored in the memory. Similar process will be performed to capture each of the substrate metrology marks 161. In another embodiment, instead of moving the imaging unit 120, the control unit 110 causes the base plate 180 to move such that the imaging unit 120 is positioned above of the substrate metrology mark 161 (corresponding to FIG. 3A).

Subsequently, imaging unit 120 is moved to a position above a die metrology mark 151 by a driving mechanism as illustrated in FIG. 3B. Accordingly, images of the die metrology mark 151 and can be taken. As shown in FIG. 3B, while the bonding head 130 carrying the die is moving toward the destination substrate 160, the control unit 110 causes the imaging unit 120 to continuously capture the image of each of the die metrology mark 151 and storing the captured images in the memory. The die metrology mark 151 is recorded in the same global/tool coordinate system as the substrate metrology mark 161 with positional and orientational information. Similar process will be performed to capture each of the die metrology marks 151. In another embodiment, instead of moving the imaging unit 120, the control unit 110 causes the substrate stage 170 to move such that the imaging unit 120 is positioned above of the die metrology mark 151 (corresponding to FIG. 3B).

Upon being recorded in the global coordinate system, the control unit 110 performs superposition of the image of the substrate metrology mark 161 and die metrology mark 151 by digitally superposing the marks to form a simulated interference pattern. As discussed above, the image of the die metrology mark 151 is continuously captured while the bonding head 130 moves toward destination substrate 160. In an embodiment, the image of the die metrology mark 151 can be captured at least twice while the bonding head 130 moves toward destination substrate 160. In the present embodiment, the image of die metrology mark 161 immediately before the die 150 comes into contact with the destination substrate 160 is used to simulate the interference pattern. Thus, the error from die alignment can be obtained and adjusted prior to bonding the die to the destination substrate 160. In the context of the present embodiment, superposing the marks means a point-by-point multiplication of the image intensities of the two images in the spatial domain. For example, the image of the substrate metrology mark 161 is stored in memory as a substrate array of pixels, and the image of the die metrology mark 151 is stored in memory as a die array of pixels. In the processing of superposing the marks, each pixel in the substrate array of pixels is multiplied by the corresponding die array of pixels to form a simulated array of pixels that represents a simulated interference pattern. Storing these images in the global coordinate system can include shifting the relative positions of the image. This shifting can include determining an amount of shifting based on the relative position of the stage, the relative position of the substrate metrology mark to the substrate bonding pads, and/or the relative position of the die metrology mark to the die bonding pads.

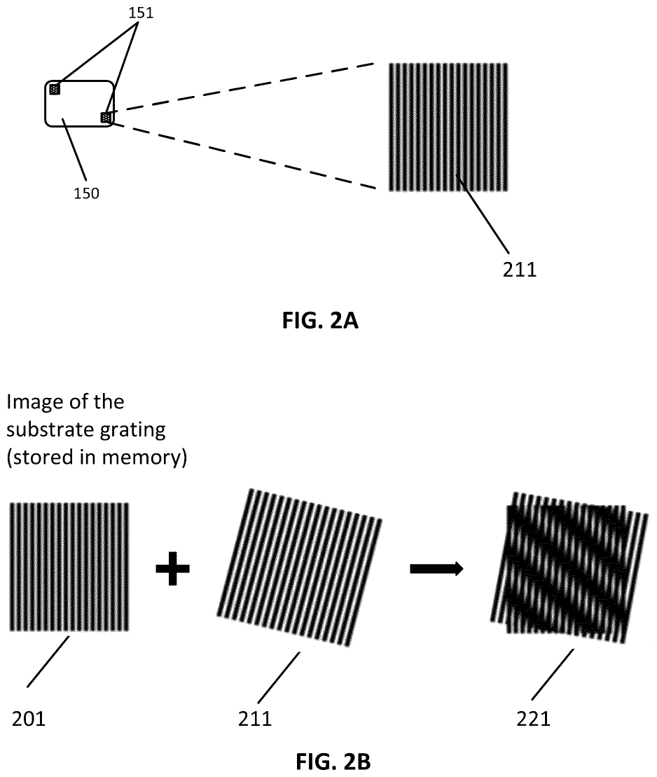

FIG. 2A is a top-down view of the die 150 with metrology marks 151 of FIG. 1 in accordance with an embodiment of the present disclosure. The die 150 may be a part of an integrated circuit product that includes electrical elements. The die 150 may include one or more transistors, supporting circuitry to route electrical signals to other integrated circuit components.

In this embodiment, the dies 150 may include one or more die metrology marks 151 which are formed on the non-active or back surfaces of the die on a surface opposite a bonding surface of the die. The die metrology mark 151 may be formed of grating lines as illustrated in the die metrology mark image 211. In the illustrative embodiment, the pitch between grating lines of the die metrology mark 151 may be 0.5 μm to 1 μm. In another embodiment, the pitch of the metrology mark may be 0.5 μm to 20 μm. When moiré amplification is used, the substrate metrology marks 161 will have a different pitch than the die metrology marks 151. For example, if the difference in the pitches is on the order of 2-3% than a relatively large moiré amplification can be achieved. The width of each grating line may be any suitable amount, such as 10-90% of the pitch. The overall size of the substrate metrology mark and the die metrology mark may be the same or different depending on actual application. The shape of the substrate metrology mark and the die metrology mark may be square, rectangular, or any other shapes. However, the direction and orientation of the gratings are not limited to this example.

The grating lines of the metrology marks may be formed by any suitable material including but not limited to silicon, silicon oxide, metal, dielectric, and/or any other suitable material that reflects or absorbs light. An example of the gratings of substrate metrology marks 161 and die metrology marks 151 is moiré gratings. The gratings or patterns of the substrate metrology marks 161 and die metrology marks 151 shall be complementary to each other such that when the patterns are overlayed on top of one other, a moiré interference pattern may be observed and die metrology error can be determined. The process of determining metrology mark errors based on these metrology marks will be explained in further details below in FIG. 2B.

FIG. 2B illustrates the images of substrate metrology die metrology mark captured by imaging unit 120 and stored in the memory. In this example, substrate metrology mark image 201 and die metrology mark image 211 are both images of the moiré gratings stored in the memory. The simulated interference pattern 221 is a moiré interference pattern that is formed by superposing a substrate metrology mark image 201 and die metrology mark image 211. If the pitch of the first metrology mark is p₁ and the pitch of the second metrology mark is p₂, then the pitch of the resultant moiré interference fringe has a period P_{F} given by equation (1) below:

$${P}_{F} = \frac{{p}_{1} {p}_{2}}{\vert {p}_{1} - {p}_{2} \vert} \qquad ( 1 )$$

As an example, p₁=3.6 μm, p₂=3.7 μm would produce a moiré interference pattern with period, P_{F}=133.2 μm. The displacement magnification, D_{mag} for the metrology is estimated by the following equations (2):

$${D}_{mag} = \frac{{O}_{mag} * {P}_{F} * k}{{P}_{av}} \qquad ( 2 )$$

$${P}_{av} = \frac{2 {p}_{1} {p}_{2}}{{p}_{1} + {p}_{2}} \frac{1}{{P}_{av}} = \frac{1}{2} ( \frac{1}{{p}_{1}} + \frac{1}{{p}_{2}} )$$

where, O_{mag}=optical magnification (1×, 5×, 10×, 20×, 50×, 100×) of the imaging unit 120;
P_{F}=Fringe period/pitch;
Pₐᵥ=Average grating period/pitch;
k=moiré pattern factor=2 if the two complementary grating patterns are designed to produce counter propagating fringes else k=1;
   The displacement magnification is the amplification that is observed by the imaging unit 120 by relative displacement of the die metrology mark image 211 relative to the substrate metrology mark image 201. For example, if the substrate metrology mark image 201 has a pitch p₁=3.6 μm, the die metrology mark has a pitch p₂=3.7 μm that produce counter propagating fringes, the fringe pitch (P_{F})=133.2 μm and assuming the imaging unit 120 has an optical magnification of 5×, the displacement magnification D_{mag} would be 365. This means that a 10 nm motion of one of the metrology marks relative to the other would produce a 3.65 μm motion of the moiré interference fringes on the CCD/CMOS sensor of the imaging unit 120. Additional improvement in displacement detection sensitivity can be obtained by phase analysis of the counter propagating moiré fringes, high dynamic range with large number of pixels sensors. In another embodiment, Fourier analysis may be performed on the simulated interference pattern. The phase information from the Fourier analysis can then be used to obtain using these algorithmic approaches, the relative alignment error (X, Y, θZ) for each die metrology mark image 211 is obtained relative to the substrate metrology mark image 201 offset. Based on the above equation, the metrology mark positioning error (Error_{MetrologyMark}) between a substrate metrology mark image 201 and die metrology mark image 211 can be determined using conventional technique based on image analysis of the simulated interference pattern. The process shall be repeated for each of the metrology marks.

By digitally simulating the interference pattern using the stored metrology mark of the substrate and backside metrology mark of the die, the metrology marks do not need to be physically overlayed above one other. Hence, the metrology marks do not need to be formed in any dedicated regions on the substrate or the die. Further, the images of the substrate metrology mark and the die metrology marks can be obtained by imaging devices with low NA and low magnification with longer working distances and large depths of field (DoF). In another embodiment, the images of the substrate metrology mark and the die metrology marks can be obtained by imaging devices with high NA. Also, by not requiring the metrology marks to be physically overlayed above each other, no imaging through the die is necessary to obtain the interference pattern. Further, images of die metrology marks 151 can be captured and interference pattern can be formed in real time while the die is in motion. That is, metrology mark error can be determined in real time while the bonding head 130 is bringing die 150 toward destination substrate 160. The interference pattern is not limited to moiré patterns. For example, the metrology marks 151 and 161 may be a box-in-box, bar in bar, cross-in-cross, checkerboard, bullseye, vernier scale marks, or cross-in-box patterns. Optics design and image analysis algorithms used for extracting alignment error information would be different to achieve as fine sensitivity as the moiré interference-based metrology.

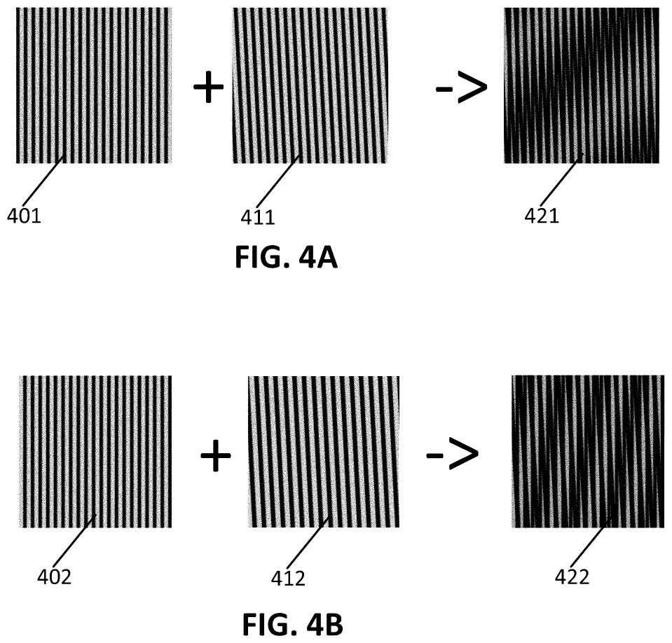

FIGS. 4A and 4B illustrate examples of the metrology marks images obtained using different parameters. The substrate metrology mark image 401 and die metrology mark image 411 are shown in FIG. 4A and are stored in memory of the control unit 110. The substrate metrology mark image 401 of FIG. 4A shows an image with 800×800 pixels (px), p₁=20 px. Die metrology mark image 411 shows an image with p2=21 px. It can be seen that the gratings of die metrology mark image 411 has a slight rotation relative to the gratings of the substrate metrology mark image 401. Hence, when the images are digitally superimposed to form an interference pattern, the light and dark region on the simulated interference pattern 421 can be observed. Based on the equation, the resultant moiré interference pattern P_{F} of 420 px can be determined as follows:

$${P}_{F} = \frac{( {p}_{1} {p}_{2} )}{( {p}_{1} - {p}_{2} )} = 420 px$$

FIG. 4B illustrates another example for determining metrology mark errors. The substrate metrology mark image 402 of FIG. 4B shows an image with 800×800 pixels (px), p1=20 px. Die metrology mark image 412 shows an image with p₂=25 px. It can also be seen that a slight rotation in the gratings of die metrology mark image 412 relative to the gratings of the substrate metrology mark image 402. Hence, the light and dark region on the simulated interference pattern 422 can be observed. Using the equation above, the resultant moiré interference pattern P_{F} of 100 px can be determined. Accordingly, the metrology mark errors can be determined based on the image analysis of the moiré interference pattern.

Accordingly, the metrology mark error of die relative to the substrate can be obtained by observing the simulated interference pattern. In this example, the substrate metrology mark and die metrology mark need not be directly placed above one another. Instead, moiré interference pattern is generated digitally by superposing the substrate metrology mark and die metrology mark.

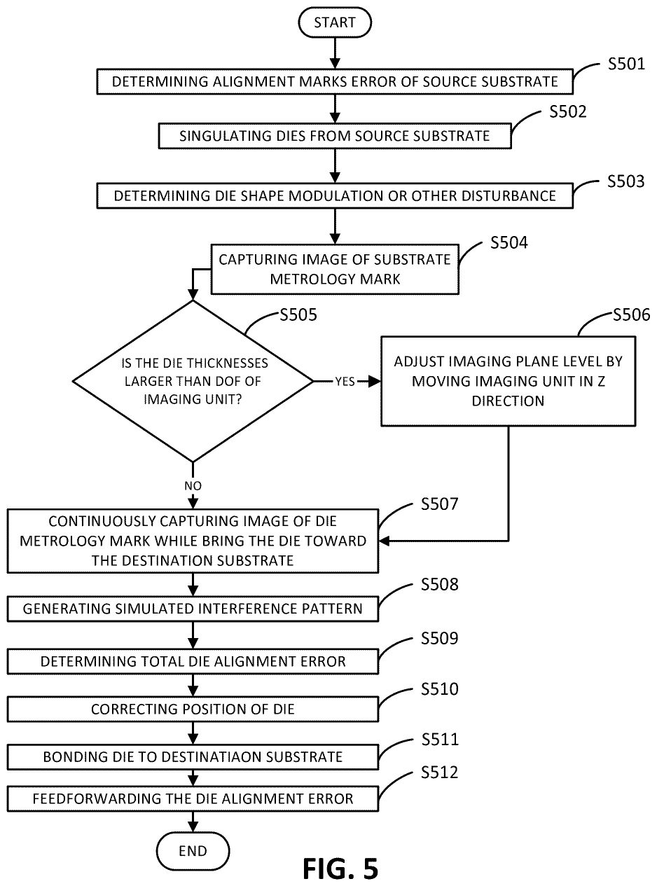

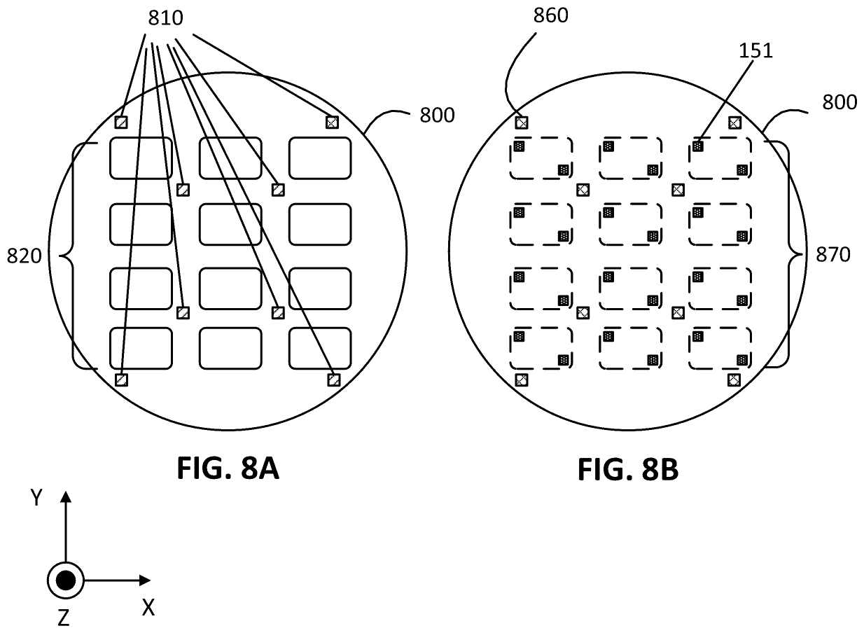

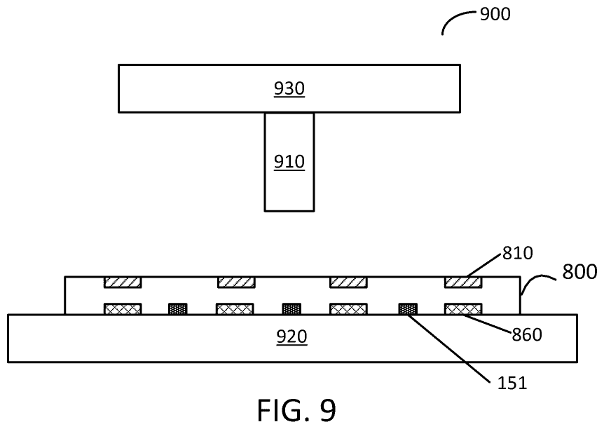

FIG. 5 is a flowchart illustrating an exemplary operation for determining an alignment error of a die and bonding the die to a destination substrate. For illustrative purposes, FIG. 5 will be explained with reference to the figures discussed above. The process begins in step S501 to determine alignment marks error of the source substrate 800. The determination of alignment marks error will be explained below with reference to FIGS. 8A, 8B, and FIG. 9. Referring to FIGS. 8A and 8B, an active side and the opposite non-active side of the source substrate 800 prior to a singulation process are shown, respectively, in accordance with an embodiment of the present disclosure. An array of dies 820 are fabricated on the active side of the source substrate 800. The non-active side of the source substrate 800 in FIG. 8B shows the backside of the array of dies 820, as die backsides 870. The dotted outline of the array of die backsides 870 indicates the ideal position of the alignment marks with respect to the dies on the active side. Each of the die backsides 870 includes one or more die metrology marks 151 in the non-active side as discussed above with respect to the singulated dies bonded on the destination substrate 160 of FIG. 1.

As shown in FIG. 8A, a set of active side alignment marks 810 are fabricated on the unused area (non-die area for example the streets or scribe line regions) of the source substrate 800. While an array of 3×4 is shown in FIG. 8A, the array of dies can be arranged in other patterns. The active side alignment marks 810 can be dispersed in any pattern so long as the marks are fabricated in the unused portion of source substrate 800. In an alternative embodiment, some but not all of the active side alignment marks are fabricated in the unused portion of the source substrate 800. In some embodiments, alignment marks on the active side of source substrate 800 are prefabricated in the source substrate 800. These active side alignment marks 810 are representative of the alignment of the circuit/features on the active side of the source substrate 800.

Based on the positions of the set of active-side alignment marks 810, a set of corresponding non-active side alignment marks 860 are fabricated on the non-active side (backside) of the source substrate 800 as illustrated in FIG. 8B. These non-active side alignment marks 860 are placed on the non-active side which are collinear with the active side alignment marks 810 along with die metrology marks 151.

Before the non-active side alignment marks 860 are made and the metrology information is obtained and stored in the memory of control unit 110, the non-singulated source substrate 800 can be thinned down, if necessary, to a desired thickness of for example less than 0.1 mm. The thinning techniques may be performed using one or more back grinding processes such as mechanical grinding, chemical mechanical planarization (CMP), wet etching, dry etching, plasma etching, or any other process of removing material in a controlled manner.

The active side of the source substrate 800 having a set of active side alignment marks 810 and the non-active side having a set of non-active side alignment marks 860. Thereafter, metrology can be performed by using an optical device such as a microscope, camera, or beam splitter that is capable of seeing through the source substrate 800. This may include an Infrared (IR) microscope or a vision system to look through IR transparent substrates. The metrology can also be performed a dual vision system that simultaneously obtains information from both sides of the substrate. The metrology can also be performed using an extremely stable metrology system that is able to provide repeatable measurements from both sides of the substrate in a sequential manner.

FIG. 9 is an exemplary configuration for measuring alignment marks of the source substrate 800. In this example, a measurement system 900 may be set up outside of metrology and bonding apparatus 100 of FIG. 1. In another embodiment, the measurement system 900 is incorporated within the metrology and bonding apparatus 100. The measurement system 900 can be controlled by control unit 110 of FIG. 1 or controlled by another controller in communication with control unit 110. According to FIG. 9, source substrate 800 is placed on a substrate stage 920 with active side facing upward. The substrate stage 920 can include a chuck (not shown) for holding the source substrate 800. The substrate stage 920 is capable of moving the source substrate 800 in the X, Y, Z and/or tilt directions. The active side of the source substrate 800 having a set of active side alignment marks 810 and the non-active side having a set of non-active side alignment marks 860. Thereafter, metrology can be performed by using an optical device 910 such as a microscope, camera, or beam splitter that is capable of seeing through the source substrate 800. This may include an Infrared (IR) microscope or a vision system to look through IR transparent substrates. The optical device can be coupled to a movable holding device 930. The optical device 910 performs metrology to obtain positional information of the active side alignment marks 810 and non-active side alignment marks 860 and compares them against each other to obtain the X-direction error information and the Y-direction error information or the X-direction error information, Y-direction error information, and rotation (θZ) error information and provides the measurement result to the control unit 110 or to a processor (not shown) connected to the control unit 110 via a network. To enable observing both sets of marks 810 and 860, either the substrate stage 920 can move in Z-axis direction or the optical device 910 can use a Z-motion stage (not shown), which may be part of the holding device 930, to move the optical device in the Z-axis direction. Alternatively, the depth of field of the optical device 910 could be designed such that both sets of marks 810 and 860 are able to produce good contrast at a single relative location of the optical device to the substrate i.e. the depth of field of the optical device is large enough that both sets of marks 810 and 860 are in focus at a single location.

Based on the measurement result, the control unit 110 determines the alignment marks placement errors in the X, Y, and θZ (rotational) directions based on the offset between the measured positions of the active-side alignment marks 810 and non-active-side alignment marks 860 on the source substrate 800, where

$${Error}_{AlignmentMarks} ( i ) = \{ {e}_{xfronttoback} ( i ) , {e}_{yfronttoback} ( i ) , {e}_{θ fronttoback} ( i ) \} \qquad ( 3 )$$

The Error_{AlignmentMarks} (i) is a measured placement error for each alignment mark (i) for a plurality of alignment marks 810 and 860 on the source substrate 800 at a specific position (x, y).

In one embodiment, the alignment marks may be thin marks that only allow measurement of the placement error in one or two of the dimensions {e_{xfronttoback}, e_{yfronttoback}, e_{θfronttoback}}. The full set of Error_{AlignmentMarks} may be fitted to a model f that describes the placement error (eₓ, e_{y}, e_{θ}) of the alignment marks across the source substrate 800 as a function of the mark location on the source substrate. The model f may also take into account the type of errors associated with the fabrication technique used to fabricate the marks. The model f may then be used to estimate the placement error of the metrology marks 151 on the non-active side of the dies. A simple model f, which may be useful when there is a high density of alignment marks, and the errors are small, is to take a local average of the nearest alignment marks. In another embodiment, a model which takes into account additional high spatial frequency errors such as magnification, skew, trapezoidal and high order polynomials could also be included as offsets and correction to die alignment control algorithm. In another embodiment, a linear least squares fitting may be performed to fit n-th degree polynomial of the model f in two dimensions to the error data.

In particular, the source substrate 800 has a set of active side alignment marks 810 (A). There are N active side alignment marks Aⱼ in the set of active side alignment marks 810 (A={A₁, . . . Aⱼ, . . . A_{N}}). Each active side alignment mark j is located at an active side alignment mark position Aⱼ on the active side of the source substrate 800. Active side alignment mark position Aⱼ includes a position {A_{j,x}, A_{j,y}} in the coordinate system of the substrate (Aⱼ={A_{j,x}, A_{j,y}}).

The non-active side of the source substrate is patterned with a set of corresponding non-active side alignment marks 860 (B) and set of die metrology marks 151 (C). There are N non-active side alignment marks Bⱼ in the set of non-active side alignment marks 860 (B={B₁, . . . Bⱼ, . . . B_{N}}). Each non-active side alignment mark j is located at non-active side alignment mark position Bⱼ on the non-active side of the source substrate 800. Ideally, the non-active side alignment mark positions Bⱼ should be collinearly located with active side alignment mark positions Aⱼ but on the back side of the substrate and they may have placement errors relative to active side alignment mark positions Aⱼ. The non-active side alignment mark position Bⱼ includes a position {B_{j,x}, B_{j,y}} in the coordinate system of the substrate (Bⱼ={B_{j,x}, B_{j,y}}).

Referring to FIG. 8B, there are M die metrology marks in the set of die metrology marks 151 (C={C₁, . . . Cᵢ, . . . C_{M}}). Each die metrology mark i is located at die metrology mark position Cᵢ on the non-active side of the source substrate 800. The die metrology mark position Cᵢ includes a position {C_{i,x}, C_{i,y}} in the coordinate system of the substrate (Cᵢ={C_{i,x}, C_{i,y}}). There is at least one die metrology mark 151 for each die on the source substrate 800.

Returning to the flow, in step S502, the source substrate 800 is diced (singulated) into individual dies after the measurement. Each of the dies includes one or more metrology marks as illustrated in FIG. 2A. The one or more metrology marks are on the outer side or backside (side that is opposite the side to be bonded to the destination substrate) of each of a plurality of dies. Any suitable metrology marks may be located at different locations on the substrate or the frame. The metrology marks may include a pattern such as grating lines as illustrated in FIG. 2A. Each of the grating lines that form the metrology mark may be any suitable material, such as silicon, silicon oxide, metal, dielectric, and/or any other suitable material that reflects or absorbs light in a manner that is in contrast with the rest of the die. The pitch between grating lines of the overlay metrology mark may be uniform or non-uniform.

Next, in step S503, each of the singulated die is sequentially picked up by the bonding head 130 via bonding chuck 140. The metrology and bonding apparatus 100 determines the die shape modulation or any other disturbance. The singulated die may be treated after being singulated and being loaded onto the bonding head 130. The bonding head 130 can include the ability to modulate a shape of the die during the bonding process. For example, the die 150 may be bowed out at an initial stage of the bonding process before being made to conform to the shape of the destination substrate 160 at the end of the bonding process. The shape of the die can be predicted based on the size of the die, thickness of the die, material of the die, and an amount of deformation applied to the die. For instance, the amount of deformation can be applied by supplying a pressurized fluid to the die through cavity 131. The amount of deformation can be applied by supplying the pressurized fluid to cavity 131 behind a chucking surface holding the die. The amount of deformation may result in a tilt and/or curvature which may appear in the die metrology mark image. Consequently, the die metrology mark image stored in the memory can be adjusted to compensate for the tilt and/or curvature using standard image analysis techniques when the shape of the surface is known. In another embodiment, when generating the simulated interference pattern in step S508 (to be discussed below), adjustment is performed to the simulated interference pattern by taking into account the shape of the surfaces on which the metrology marks are formed.

In step S504, an imaging unit such as imaging unit 120 of FIG. 2 captures one or more images of the substrate metrology mark 161 and records the captured images in a global coordinate system as described above. In an alternative embodiment, step S504 is performed prior to steps S502. In another embodiment, step S504 is performed prior to the die being received by the metrology and bonding apparatus 100 in step S502. After each of the substrate metrology marks have been captured and recorded, the flow proceeds to step S505.

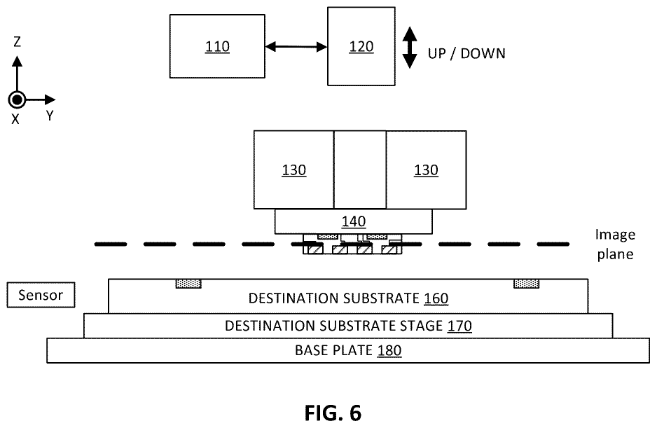

In step S505, thickness of the dies 150 is obtained. The thickness of the dies may be obtained via a measurement. The measurement may be performed with a gap sensor (not shown), for example, by an optical sensor (such as spectral interference sensors, interferometers, laser triangulation sensors, or other sensors such as air gauge, capacitive sensors, inductive sensors) provided on a bridge (not shown) on which imaging device 120 are mounted, the substrate stage 170, or the base plate 180. In another embodiment, the thickness may be obtained outside of the metrology and bonding apparatus 100 and recorded prior to the measurement process. In the event the die has a thickness larger than the Depth of Field (DoF) of the imaging unit 120 (Yes in step S505), the process proceeds to S506. If the die has a thickness larger than the DoF of the imaging unit 120, high quality images of the metrology marks cannot be obtained. Thus, the image plane should be adjusted to compensate for the DoF limitation of the imaging unit 120. FIG. 6 illustrates exemplary solutions for compensating DoF limitation of the imaging unit 120. In FIG. 6, the imaging unit 120 is moved upward or downward such that the image plane can be properly adjusted. By moving the imaging unit 120 upward/downward in a Z direction, the image of the die metrology mark 151 is adjusted to a DoF range that is suitable for the imaging unit 120 so that images of the metrology mark can be properly focused. In another embodiment, the imaging unit 120 can be adjusted by changing one or more optical components to change the position of the DoF range. In another embodiment, the imaging unit 120 includes zoom and autofocus capabilities such that the image target can be focused without mechanically moving the imaging unit 120 upward or downward. The bonding head 130 may move towards the destination substrate stage 180 during the bonding process. In an embodiment, the imaging unit 120 moves along with the bonding head 130 such that the image plane is maintained during the bonding process. In an alternative embodiment, an optical element within the imaging unit 120 moves to maintain the image plane during the bonding process. In an alternative embodiment, the control unit 110 transforms the die metrology mark image to correct for image plane focus errors. In another alternative embodiment, the destination substrate is lowered such that the bonding plane is below the image plane by an amount related to the thickness of the die such that the back of the die is within in the depth of focus as the bonding head approaches the bonding plane during the bonding process.

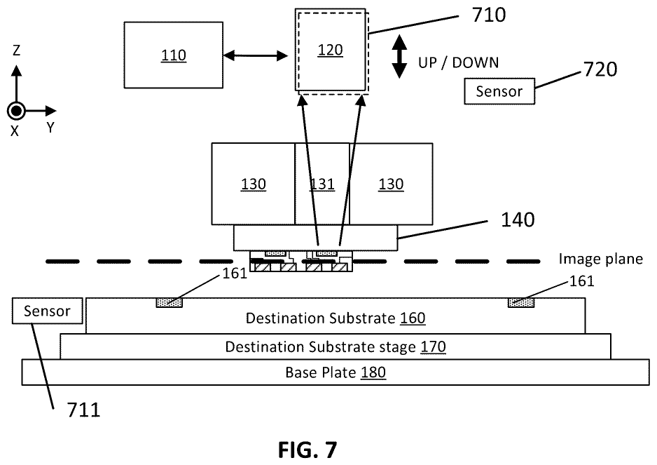

FIG. 7 illustrates the unintended parasitic errors, or offsets that occurred during the capturing of the first image and the second image, which may result in such moving parts. For example, the dotted object 710 of FIG. 7 shows the actual position of the imaging unit 120 after the imaging unit 120 is moved upward, which represents an offset from the intended position of the imaging unit 120. The offset, or parasitic errors, (non-straightness, pitch, roll, yaw) εₓ(z), ε_{y}(z), ε_{θ}(z) associated with the substrate's motion or imaging unit's motion can be measured, for example, with optics sensor 720 based on the following equation (4):

$${Offset}_{opticsZmotioninduced} ( z ) = [ {ε}_{x} ( z ) , {ε}_{y} ( z ) , {ε}_{θ} ( z ) ] = ( {Δ}_{measured} ( x , y , θ ) - {Δ}_{intended} ( x , y , θ ) ) \qquad ( 4 )$$

where Δ_{measured}(x, y, θ) is the change in position as measured by substrate sensor 711 or by the optics sensor 720, and A_{intended}(x, y, θ) is the change in intended position.

In the event the die does not have a thickness larger than the Depth of Field (DoF) of the imaging unit 120 (No in step S505) or step S506 is completed, the flow proceeds to step S507. In step S507, the control unit 110 causes imaging unit 120 to continuously capture the image of the die metrology mark 151 and record the captured image in a global coordinate system as die approaches the destination substrate in the bonding process. The die modulation may also change during the bonding process. After each of the die metrology mark has been captured and recorded, the flow proceeds to step S508.

As the bonding head 130 is moving the die 150 toward the destination substrate 160, a series of images of die metrology marks 151 can be continuously captured in real time, for example, in 15 Hz, 30 Hz, 60 Hz, 120 Hz, or 240 Hz interval. However, specialized imaging units with higher speed can also be used. Accordingly, a corresponding series of interference pattern can be generated. As a result, die metrology mark error at any specific position can be detected when the bonding head is moving toward the destination substrate. Now that both the substrate metrology marks 161 and die metrology marks 151 with positional and orientational information are captured and recorded in the same coordinate system, the control unit 110 generates a simulated moiré interference pattern by superposing the substrate metrology mark 161 and die metrology mark 151. In this embodiment, immediately before die 150 makes contact with destination substrate 160, the bonding head 130 can temporarily stop moving toward the destination substrate 160. At this time, the image of die metrology mark 151 is captured and used for the purpose of generating the simulated moiré interference pattern. Based on the simulated superposed interference pattern, metrology mark error in X, Y, and θZ directions can be determined. As previously discussed, when generating the simulated interference pattern, die shape modulation and/or disturbance information obtained in step S502 can also be used to adjust the simulated interference pattern.

In step S509, based on the simulated interference pattern, metrology mark error can be determined as described above. The total die alignment error for die i can be obtained by combining the Error_{AlignmentMarks}(i), Offset_{opticsZmotioninduced}(Z), and Error_{MetrologyMark} as follows:

$$Total Die Alignment Error = {Error}_{AlignmentMarks} ( i ) + {Offset}_{opticsZmotioninduced} ( z ) + {Error}_{MetrologyMark} \qquad ( 5 )$$

In the event that Error_{AlignmentMarks}(i), Offset_{opticsZmotioninduced}(Z), or Error_{MetrologyMark} is unattainable or unavailable, the Total Die Alignment Error can be determined by at least one of Error_{AlignmentMarks}(i), Offset_{opticsZmotioninduced}(Z), or Error_{MetrologyMark}.

In step S510, control unit 110 causes bonding head 130 to correct the position of die 150 based on Total Die Alignment Error obtained in step S509. In another embodiment, only metrology mark error is used as Total Die Alignment Error in correcting position of die 150. The die 150 is then bonded to the destination substrate in step S511. Based on the error information, the metrology system or an operator of the metrology and bonding apparatus may make necessary positional adjustment to minimize the alignment error for the next die to be bonded. After the die is aligned with the substrate in step S510 as determined by the simulated interference pattern, the bonding head 130 moves toward the destination substrate 160 until die 150 makes contact and bonds with destination substrate 160. The bonding method is not limited to a specific bonding method. For example, the bonding method may be bonding using an adhesive, bonding by hybrid bonding, atomic diffusion bonding, vacuum bonding, bump bonding or the combination of the like.

After bonding, in step S512 the Total Die Alignment Error can also be recorded in a database on a network. Such error information can be used to feedforward corrections of future dies to be bonded. The other dies singulated from source substrate 800 in step S502 may subsequently be bonded to destination substrate 160 by repeating steps S503 to S511 as described above.

### Embodiment of Article Manufacturing Method

A method of manufacturing an article (a semiconductor IC element, a liquid crystal element, a MEMS, or the like) using the above-described apparatus will be described. The article manufacturing method according to the embodiment of the present disclosure is suitable for, for example, manufacturing an article such as a microdevice (for example, a semiconductor device) or an element having a microstructure. The article can include a plurality of elements. Each element includes a plurality of interconnects that allow communication between the elements. The article manufacturing method according to the embodiment can include additional steps of bonding a die to a destination substrate using the above-described measurement and bonding apparatus, a step of processing the destination substrate to which the is the dies are bonded, and a step of manufacturing an article from the processed first member. The subsequent step is another known step including probing, dicing, annealing, bonding, packaging, and the like. The article manufacturing method according to the embodiment is superior to a conventional method in at least one of the performance, quality, productivity, and production cost of an article.

### OTHER EMBODIMENTS

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like. While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

What is claimed is:

1. A bonding system comprising:
a bonding chuck configured to releasably secure a die;
a substrate chuck configured to releasably secure a first substrate;
an imaging device configured to capture:
a first image on an object, the first image includes a first metrology mark, the first metrology mark includes a first pattern, wherein the object is one of:
the first substrate; and
a frame that has a fixed positional relationship with the substrate chuck; and
a second image on a surface of the die, the second image includes a second metrology mark, the second metrology mark includes a second pattern captured while the bonding chuck is moving toward the substrate chuck;
at least one memory storing instructions; and
at least one processor that executes the stored instructions, which cause the at least one processor to:
receive the first image and the second image;
superpose the first pattern and the second pattern to form a simulated interference pattern;
determine a metrology mark error based on the simulated interference pattern in X, Y and θZ directions;
obtain the die alignment error based on alignment marks placement error of a second substrate of the die, and the metrology mark error; and
send instructions to adjust a position of the die chuck relative to the first substrate, before the die is brought into contact with the first substrate, based on the die alignment error.

2. The bonding system of claim 1, wherein the at least one processor further executes the stored instructions to:
record the first image to a global coordinate system based on a first positional information of the first image in the memory; and
record the second image to the global coordinate system based on a second positional information of the second image in the memory.

3. The bonding system of claim 1, wherein the die alignment error is further obtained based on offsets that occurred during the capturing of the first image and the second image.

4. The bonding system of claim 1, wherein the at least one processor executes the stored instructions to form the simulated interference pattern that is adjusted based on die shape modulation as the die is being brought into contact with the first substrate.

5. The bonding system of claim 1, wherein the determined die alignment error includes errors in X, Y, and θZ directions.

6. The bonding system of claim 1, wherein the at least one processor executes the stored instructions to obtain the alignment marks placement error based on offsets between positions of an active-side alignment marks on an active side of the second substrate and positions of a first non-active side alignment marks on a non-active side of the second substrate in the X, Y, and θZ directions.

7. The bonding system of claim 1, wherein the at least one processor executes the stored instructions to form the simulated interference pattern takes into account an offset that occurred during the capturing of the first image and the second image, when the imaging device and the first substrate are moved relative to each other in a Z direction to accommodate for the depth of field (DoF) limitation of the imaging device, and
wherein the offset occurred during the capturing of the first image and the second image are obtained by at least one of:
measuring positions of the first substrate relative to intended positions of the first substrate as a relative distance between the imaging device and the first substrate is adjusted; and
measuring positions of the imaging device relative to intended positions of the imaging device as the relative distance between the imaging device and the first substrate is adjusted.

8. The bonding system of claim 1, wherein the imaging device is a camera with low numerical aperture (NA) imaging optics enabling longer working distances and large depths of field (DoF).

9. The bonding system of claim 1, wherein the metrology mark error and die alignment mark error is feedforward to the at least one processor.

10. A method of correcting an alignment error of a die with respect to a first substrate, the method comprising:
capturing, by an imaging device, a first image on an object, the first image includes a first metrology mark, the first metrology mark includes a first pattern;
capturing, by the imaging device, a second image on a surface of the die, the second image includes a second metrology mark, the second metrology mark includes a second pattern captured while the die is moving toward the first substrate;
superposing the first pattern and the second pattern to form a simulated interference pattern;
determining a metrology mark error based on the simulated interference pattern in X, Y and θZ directions;
obtaining the die alignment error based on alignment marks placement error of a second substrate of the die, and the metrology mark error; and
adjusting a position of the die, before the die is brought into contact with the first substrate, based on the die alignment error.

11. The method of claim 10, further comprising:
recording the first image to a global coordinate system based on a first positional information of the first image in a memory; and
recording the second image to the global coordinate system based on a second positional information of the second image in the memory.

12. The method of claim 10, wherein the die alignment error is further obtained based on offsets that occurred during the capturing of the first image and the second image.

13. The method of claim 10, wherein the simulated interference pattern is adjusted based on die shape modulation as the die is being brought into contact with the first substrate.

14. The method of claim 10, wherein the object is the first substrate.

15. The method of claim 10, wherein the object is a frame that has a fixed positional relationship with the first substrate when the first substrate is releasably secured by a substrate chuck.

16. The method of claim 10, wherein the first pattern and the second pattern comprise a plurality of uniformly or non-uniformly spaced gratings.

17. The method of claim 10, wherein the determined die alignment error includes error in X, Y and θZ directions.

18. The method of claim 10, wherein the first pattern and the second pattern are complementary patterns that includes one or more of: box in box, bar in bar, cross-in-cross, checkerboard, bullseye, moiré patterns, vernier scale marks, or cross-in-box pattern.

19. The method of claim 10, wherein the alignment marks placement error is determine based on offsets between positions of an active-side alignment marks on an active side of the second substrate and positions of a first non-active side alignment marks on a non-active side of the second substrate in the X, Y, and θZ directions.

20. The method of claim 10, wherein the offset occurred during the capturing of the first image and the second image, when the imaging device and the first substrate are moved relative to each other in a Z direction to accommodate for the depth of field (DoF) limitation of the imaging device, and
wherein the offset occurred during the capturing of the first image and the second image are obtained by at least one of:
measuring positions of the first substrate relative to intended positions of the first substrate as a relative distance between the imaging device and the first substrate is adjusted; and
measuring positions of the imaging device relative to intended positions of the imaging device as the relative distance between the imaging device and the first substrate is adjusted.

21. The method of claim 10, wherein the imaging device is a camera with low numerical aperture (NA) imaging optics enabling longer working distances and large depths of field (DoF).

22. The method of claim 10, wherein the metrology mark error and die alignment mark error is feedforward to a control system.

23. A method of manufacturing an article comprising:
an alignment method of correcting an alignment error of a die with respect to a first substrate, the alignment method comprising:
capturing, by an imaging device, a first image on an object, the first image includes a first metrology mark, the first metrology mark includes a first pattern;
capturing, by the imaging device, a second image on a surface of the die, the second image includes a second metrology mark, the second metrology mark includes a second pattern captured while the die is moving toward the first substrate;
superposing the first pattern and the second pattern to form a simulated interference pattern;
determining a metrology mark error based on the simulated interference pattern in X, Y and θZ directions;
obtaining the die alignment error based on alignment marks placement error of a second substrate of the die, and the metrology mark error; and
adjusting a position of the die, before the die is brought into contact with the first substrate, based on the die alignment error;
bringing the die into contact with the first substrate; and
processing the first substrate to manufacture the article.
